(19) United States
(12) Patent Application Publication
(10) Pub. No.: US 2009/0103260 A1
(43) Pub. Date: Apr. 23, 2009

(54) PORTABLE ELECTRONIC DEVICE

(76) Inventor: Taizo TOMIOKA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/252,705

(22) Filed: Oct. 16, 2008

(30) Foreign Application Priority Data
Oct. 19, 2007 (JP) 2007-272983

(51) Int. Cl. H05K 5/04

(52) U.S. Cl. 361/679.56

(57) ABSTRACT

A portable communication terminal comprises two hollow metal cases extending at its opposite sides along its longitudinal axis. A display unit, an input unit, a microphone and the like are arranged along the longitudinal axis of the terminal, with the metal cases set at their opposite sides, and a resin is applied to the resultant structure to mold the terminal.

### CROSS-REFERENCE TO RELATED APPLICATIONS

This application is based upon and claims the benefit of priority from prior Japanese Patent Application No. 2007-272983, filed Oct. 19, 2007, the entire contents of which are incorporated herein by reference.

### BACKGROUND OF THE INVENTION

1. Field of the Invention

The present invention relates to a portable electronic device such as a mobile phone or personal digital assistant (PDA).

2. Description of the Related Art

Mobile phones, PDAs, etc., are known as portable electronic devices. Nowadays, in the field of portable electronic devices, there is an increasing demand for reduction in weight, size and thickness in order to enhance portability.

If the housing of a mobile phone is formed of, for example, a resin to reduce its weight, it is difficult to secure sufficient mechanical strength or rigidity. In light of this, a mobile communication device has been proposed, which is partially formed of a metal to thin its housing with its mechanical strength maintained at a desired value (see, for example, FIG. 3 of Jpn. Pat. Appln. KOKAI Publication No. 2007-53450).

Such portable electronic devices as the above are required to contain batteries for use during carrying. In general, batteries have capacities substantially proportional to their volumes. Therefore, to secure a sufficient capacity, batteries are formed thick. This inevitably makes thick portable electronic terminal devices that contain the batteries.

In general, in conventional mobile phones, a battery pack is attached to the transmitter-side housing such that it is stacked on a substrate or an input unit. This further increases the thickness of the housing.

### BRIEF SUMMARY OF THE INVENTION

It is an object of the invention to provide a portable electronic device that can be made thin and to have a desired mechanical strength.

To attain the object, a portable electronic device according to an embodiment of the invention comprises: a hollow metal member extending along a first axis of the device; an input unit which accepts various input operations by a user; a display unit which displays various types of information for the user; a signal processing unit; and a battery unit, wherein at least two of the input unit, the display unit, the signal processing unit and the battery unit are arranged along the first axis and the hollow metal member.

Since as described above, the portable electronic device according to the invention comprises the hollow member extending along the first axis along which a plurality of members are arranged, it can be formed thin with a desired mechanical strength secured.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view illustrating a mobile communication terminal device according to an embodiment of the invention;

FIG. 2 is a view useful in explaining how the device of FIG. 1 is assembled; and

FIG. 3 is an exploded perspective view illustrating a modification of the frame of the terminal device.

### DETAILED DESCRIPTION OF THE INVENTION

An embodiment of the invention will be described in detail with reference to the accompanying drawings.

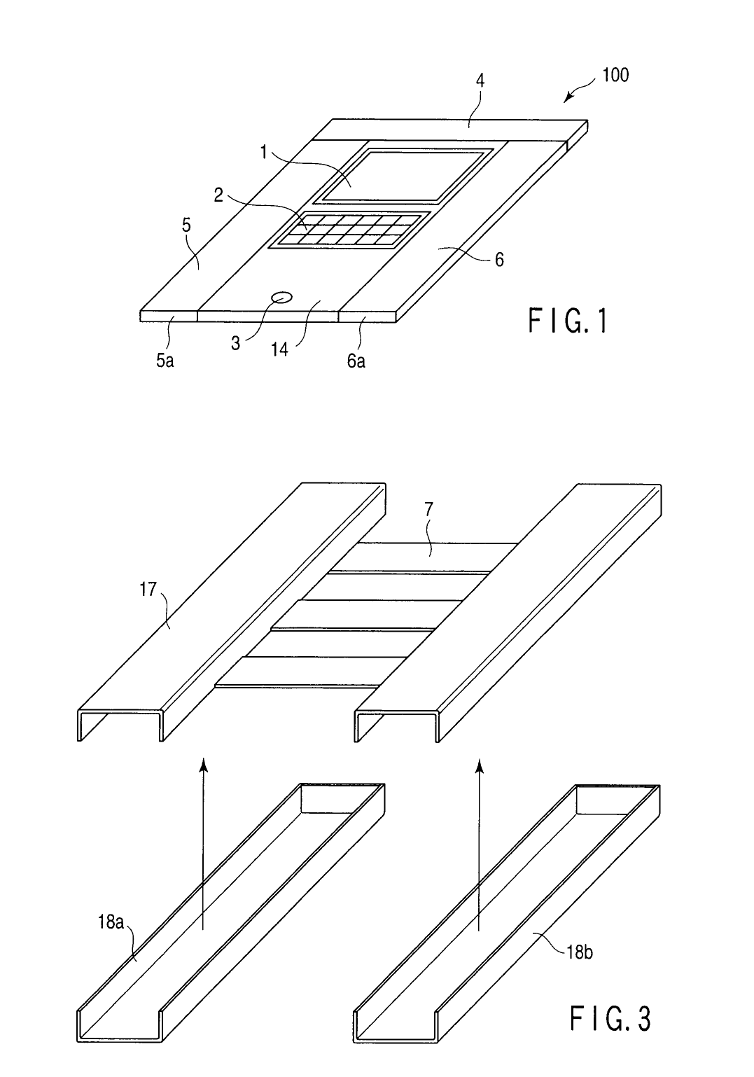

FIG. 1 is a perspective view illustrating a mobile communication terminal device 100 (hereinafter referred to simply as “the terminal 100”) such as a mobile phone, which is an example of a mobile electronic device according to the embodiment of the invention.

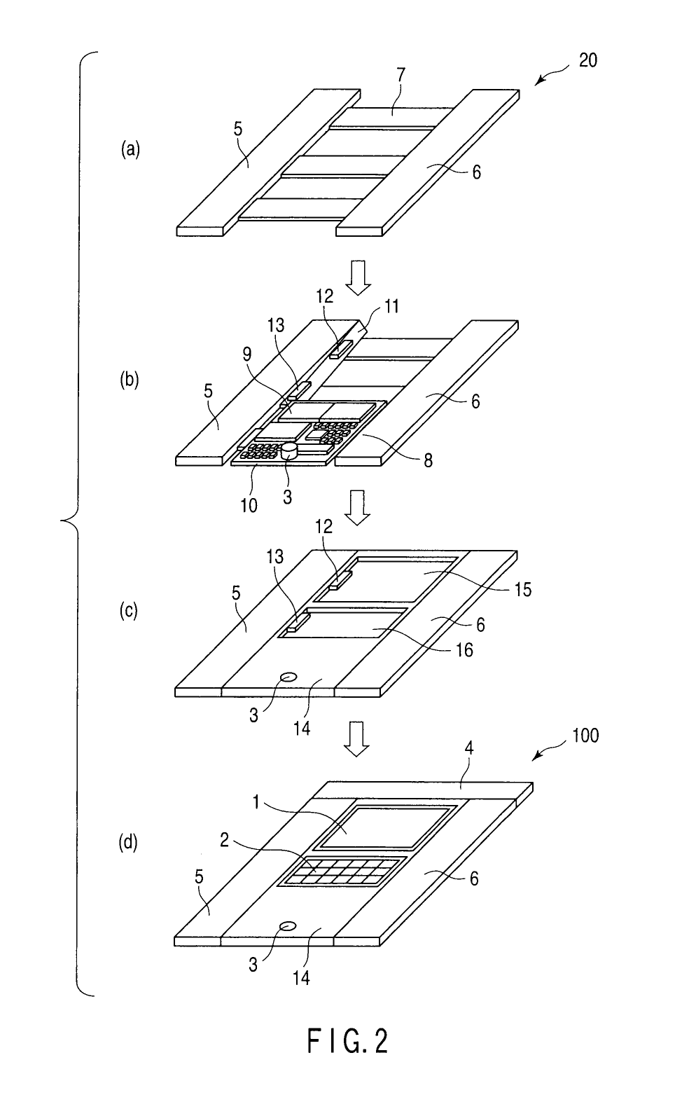

In the terminal 100, a layout in which basically, any structural member is not stacked on another is employed for thinning. The terminal 100 mainly comprises a display unit 1 for displaying various types of information for a user, an input unit 2 for accepting various input operations by the user, a signal processing unit 8, described later with reference to FIG. 2b, which incorporates a microphone 3, and an antenna unit 4. The antenna unit 4 contains, for example, an antenna and a speaker, which are not shown.

The display unit 1, the input unit 2, and the signal processing unit 8 with the microphone 3 are arranged along the longitudinal axis (first axis) of the terminal 100. Two metal cases 5 and 6 as hollow metal members are attached to the three units 1, 2 and 8 to sandwich them. A long antenna unit 4 is attached along the lateral axis (second axis) of the terminal 100 to bridge the two metal cases 5 and 6.

The metal cases 5 and 6 extend along substantially the entire longitudinal axis of the terminal 100 to make it difficult to deform the terminal 100. To this end, it is sufficient if at least one of the metal cases 5 and 6 is provided, and it is desirable to provide the cases along the longitudinal axis of the terminal 100. Further, if the metal cases 5 and 6 are provided along the longitudinal axis of the terminal 100, a space sufficient for a battery back, described later, can be secured in the cases.

As described above, the terminal 100 of the embodiment is in the shape of a substantially rectangular plate that is formed of a plurality of structural members arranged on substantially the same plane, and has a thickness of 4 mm, a width of 60 mm and a length of 110 mm. The “width” indicates the above-mentioned second axis along which the two metal cases 5 and 6 are arranged in parallel, and the “length” indicates the above-mentioned first axis along which the two metal cases 5 and 6 extend.

The two metal cases 5 and 6 can contain various electronic components, substrates, etc. In this embodiment, respective battery packs (battery units), not shown, are detachably contained in the two metal cases 5 and 6. The battery packs are, for example, lithium polymer battery packs. To enable the battery packs to be attached to and detached from the cases 5 and 6, openable/closable lids 5a and 6a are provided at ends of the cases 5 and 6 remote from the antenna unit 4, respectively. Alternatively, only one of the two metal cases 5 and 6 may contain a battery pack.

The metal cases 5 and 6 may contain other members such as the display unit 1, input unit 2 and signal processing unit 8 (described later), as well. Further, the metal cases 5 and 6 may contain electronic components such as an IC chip, vibrator and camera, as well as the above-mentioned members.

Each of the metal cases 5 and 6 is formed by bending a stainless plate with a thickness of 0.3 mm to define a space therein. The metal cases 5 and 6 have a thickness of 4 mm, a width of 13 mm and a length of 100 mm, and the battery packs contained therein have a thickness of 3.2 mm, a width of 12.5 mm and a length of 90 mm. The total volume of the two battery packs is approx. 7200 mm³, which is substantially equal to that of a battery contained in a general mobile communication terminal.

Referring then to FIG. 2, a description will be given of a method of assembling the above-described terminal 100.

Firstly, a stainless plate with a thickness of 0.3 mm is prepared, cut into portions of a preset shape, and bent to form the two hollow metal cases 5 and 6. Although in the embodiment, the metal cases 5 and 6 are formed rectangular, they may be thin elliptic cylinders.

These metal cases 5 and 6 are arranged in parallel with the longitudinal axis, and three stainless plates 7 with a thickness of 0.3 mm are interposed between the cases, thereby forming a frame 20, as is shown in FIG. 2(a). It is sufficient if the stainless plates 7 are thinner than at least the metal cases 5 and 6. Further, only a single stainless plate 7 may be used instead of the three plates 7.

The stainless plates 7 can be coupled to the metal cases 5 and 6 by welding or an adhesive. Alternatively, the stainless plates 7 may be interposed between the metal cases 5 and 6, and have their opposite ends bent and clamped on the metal cases 5 and 6. Yet alternatively, the reverse plates of the metal cases 5 and 6 may be formed integral with the stainless plates 7.

In any case, it is desirable that the stainless plates 7 be formed not to provide the entire back surface of the terminal 100, but to define gaps therebetween as shown in FIG. 2(a). This enables an arrangement space for various elements to be secured, and/or makes it easy to fill a resin, described later.

Yet alternatively, as shown in FIG. 3, members 17 each coupling the three stainless plates 7 are formed by bending parts of the metal cases 5 and 6, and the other portions 18a and 18b of the metal cases 5 and 6 are formed by bending stainless plates, thereby assembling the three members 17, 18a and 18b into the frame 20.

After that, as shown in FIG. 2(b), the signal processing unit 8, which comprises a printed circuit board 10, and a semiconductor package 9 and a microphone 3 provided thereon, is interposed between the metal cases 5 and 6 coupled to each other by the stainless plates 7. More specifically, the signal processing unit 8 is placed on one of the stainless plates 7 positioned lowest in FIG. 2(a). Namely, the stainless plates 7 are located closer to the reverse side of the terminal 100 than to the obverse surface thereof so that the signal processing unit 8 can be received within the space defined by the metal cases 5 and 6 and stainless plates 7.

The printed circuit board 10 of the signal processing unit 8 is connected to two connectors 12 and 13 via a flexible wiring board 11. The connector 12 is connected to the display unit 1, and the connector 13 is connected to the input unit 2.

The flexible wiring board 11 longitudinally extends along one side surface of the metal case 5 (i.e., along the first axis), and has an extension connected to one of the battery packs detachably received in the metal cases 5 and 6, and to the antenna and speaker contained in the antenna unit 4. When an extended portion of the flexible wiring board 11 is exposed through the upper end of the one battery pack, it is covered with the antenna unit 4.

Subsequently, the signal processing unit 8 interposed between the metal cases 5 and 6, and the flexible wiring board 11 including the connectors 12 and 13 are sealed with a resin 14 as shown in FIG. 2(c). At this time, substantially rectangular recesses 15 and 16 for receiving the display unit 1 and the input unit 2 are defined by the resin 14. The above-mentioned connectors 12 and 13 are exposed on the resin 14 along the inner side of the metal case 5. If the signal processing unit 8 and the flexible wiring board 11 are molded out of a resin, the two metal cases 5 and 6 function as parts of a mold.

After that, the display unit 1 is connected to the connector 12 and fitted in the recess 15, while the input unit 2 is connected to the other connector 13 and fitted in the other recess 16. The units 1 and 2 are adhered to the recesses 15 and 16, respectively, by an adhesive applied to the recesses.

In the embodiment, the display unit 1 and the input unit 2 are fitted in the recesses 15 and 16 defined by the resin 14 after the signal processing unit 8 and the flexible wiring board 11 are coupled to each other by the resin 14. However, the resin 14 may be applied after all members 8, 11, 1 and 2 are arranged between the metal cases 5 and 6. In any case, it is important that those members are laid out so that the connectors 12 and 13 and the flexible wiring board 11 will not be superposed thickness ways with respect to the terminal 100.

Lastly, the antenna unit 4, which contains the antenna, the speaker, etc., is connected to the resultant structure to bridge the upper ends of the two cases 5 and 6, thereby completing the terminal 100 as shown in FIG. 2(d).

As described above, in the embodiment, the elements 1, 2 and 8 of the terminal 100 are not superposed on each other, with the result that the terminal 100 can be formed extremely thin. In particular, in the embodiment, since the respective battery packs are contained in the metal cases 5 and 6, the entire thickness of the terminal 100 can be reduced to that of each battery pack, with a sufficiently battery capacity secured. Alternatively, if the thickness of the terminal 100 is slightly increased, the width of each metal case can be reduced with a sufficiently battery capacity secured, whereby the width of the terminal 100 can be reduced.

In general, when the terminal 100 is formed thin, its bending strength is reduced. However, in the embodiment, since the two hollow metal cases 5 and 6 are provided at the opposite sides of the terminal 100 along the longitudinal axis, the bending strength of the terminal 100 along the longitudinal axis is set to a desired value. Further, in the embodiment, since the respective battery packs are contained in the hollow metal cases 5 and 6, a sufficient space for the elements of the terminal can be secured, with the entire size of the terminal 100 reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

For instance, although in the above-described embodiment, the metal cases 5 and 6 are attached to the opposite sides of the terminal 100, the invention is not limited to this. At least a single metal case may be provided at one side of the terminal 100 along the longitudinal axis.

Further, although in the embodiment, the battery packs are contained in the metal cases 5 and 6, other elements may be contained in the cases. For instance, the structure may be modified such that a battery pack is contained in one of the metal cases 5 and 6, and the signal processing unit 8 is contained in the other case. In this case, the metal case can block electromagnetic waves emitted from an electronic component, such as a CPU, included in the signal processing unit 8. As a result, a metal member dedicated to shielding, which is needed in conventional electronic devices, is not necessary, thereby reducing the number of required components and hence reducing the manufacturing cost of the terminal 100.

Furthermore, although in the above-described embodiment, the stainless plates 7 are used to couple the two metal cases 5 and 6, a hollow member of the same thickness as the metal cases 5 and 6, for example, may be interposed therebetween to couple them. In this case, yet other members or electronic components can be contained in the hollow coupling member.

In addition, although in the above embodiment, all structural elements, such as the display unit 1, input unit 2, signal processing unit 8 and battery packs, are arranged at the same level, the invention is not limited to this. It is sufficient if at least the display unit 1, signal processing unit 8 and battery pack are arranged at the same level. In this case, for example, the battery pack is not contained in the metal cases 5 and 6, but is interposed therebetween, and the input unit 2 is superposed on the pack. Alternatively, the battery pack is contained in the metal cases 5 and 6, and the input unit 2 is superposed on the signal processing unit 8.

What is claimed is:

1. A portable electronic device comprising:
a hollow metal member extending along a first axis of the device;
an input unit which accepts various input operations by a user;
a display unit which displays various types of information for the user;
a signal processing unit; and
a battery unit,
wherein at least two of the input unit, the display unit, the signal processing unit and the battery unit are arranged along the first axis and the hollow metal member.

2. The portable electronic device according to claim 1, wherein at least one of the at least two units is coupled to the hollow metal member.

3. The portable electronic device according to claim 1, wherein the hollow metal member is permitted to contain units other than the at least two units arranged along the hollow metal member.

4. The portable electronic device according to claim 3, wherein the units other than the at least two units include the battery unit.

5. The portable electronic device according to claim 1, further comprising wiring extending along the first axis between the hollow metal member and the at least two units, the wiring electrically connecting the at least two units.

6. The portable electronic device according to claim 5, further comprising an antenna unit containing an antenna for wireless communication, the antenna unit being electrically connected to the signal processing unit via the wiring.

7. The portable electronic device according to claim 1, further comprising another hollow metal member which cooperates with the first-mentioned hollow metal member to hold therebetween the at least two units.

8. The portable electronic device according to claim 7, wherein the two hollow metal members are coupled to each other by at least one coupling member extending along a second axis perpendicular to the first axis.

9. The portable electronic device according to claim 8, wherein the at least one coupling member is a plate member at least thinner than the hollow metal members.
